(19) United States
(12) Patent Application Publication
(10) Pub. No.: US 2008/0224208 A1
(43) Pub. Date: Sep. 18, 2008

(54) Semiconductor device and method for fabricating the same

(75) Inventor: Yun Seok Chun, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/819,613

(22) Filed: Jun. 28, 2007

(30) Foreign Application Priority Data
Mar. 15, 2007 (KR) 10-2007-0025692

(51) Int. Cl. H01L 29/78; H01L 21/8238

(52) U.S. Cl. 257/334; 257/330; 438/212

(57) ABSTRACT

A semiconductor device includes a semiconductor substrate including an NMOS region and a PMOS region, a device isolation structure formed on the semiconductor substrate to define an active region, a recess channel structure formed in the active region, a gate insulating film disposed in the recess channel structure, and a gate including an undoped amorphous silicon layer formed over the gate insulating film, the gate filling the recess channel structure.

### CROSS-REFERENCES TO RELATED APPLICATIONS

The present application claims the benefit of priority to Korean patent application number 10-2007-0025692, filed on Mar. 15, 2007, the entire contents of which are incorporated herein by reference.

### BACKGROUND

The invention relates to a memory device. More particularly, the invention relates to a semiconductor device comprising a dual poly gate and a method for fabricating the same.

The continuous increase in integration of semiconductor devices favors the use of a three-dimensional recess channel structure and a dual poly gate structure in the semiconductor devices, so as to secure sufficient refresh characteristics and PMOS characteristics. When the dual poly gate structure is used in a semiconductor device having a three dimensional recess channel structure, several matters should be considered, such as how to dope N-type impurities with a high concentration.

It is difficult to dope impurities with a desired concentration into a gate polysilicon layer by an ion-implanting method in case of the three-dimensional recess channel structure. For example, high concentration ion-implantation and high thermal treatment are required in order to dope impurities into a gate polysilicon layer with a desired concentration in the three-dimensional recess channel structure. In this case, the penetration of P-type impurities, such as Boron (B), increases through a gate insulating film formed over the recess channel structure, and the concentration of N-type impurities, such as phosphorous (P), is lowered in the bottom of the recess channel structure.

When doping a dual poly gate structure, a high concentration counter doping process is performed for forming a PMOS to cause an abnormal interface reaction between a gate poly layer and a subsequent metal layer, thereby degrading the performance of the device. For example, although a PMOS region is exposed with a photoresist film for counter doping, the P-type impurities of high concentration change the physical property of the photoresist film, so that it is difficult to remove the photoresist film. As a result, a plasma strip step and a cleaning step is also required, which cause damage to the poly gate. As a result, the method causes topology and the abnormal interface reaction in the subsequent steps for forming a barrier layer and a metal layer, thereby degrading the performance of the device.

### SUMMARY

Embodiments consistent with the invention are directed to a semiconductor device including a dual poly gate. According to one embodiment, the dual poly gate includes an undoped amorphous silicon layer.

In one embodiment, there is provided a semiconductor device comprising a semiconductor substrate including an NMOS region and a PMOS region, a device isolation structure formed on the semiconductor substrate to define an active region, a recess channel structure formed in the active region, a gate insulating film disposed in the recess channel structure, and a gate including an undoped amorphous silicon layer formed over the gate insulating film, the gate filling the recess channel structure.

In another embodiment, a method for fabricating a semiconductor device is provided. The method comprises: providing a semiconductor substrate including an NMOS region and a PMOS region, forming a device isolation structure on the semiconductor substrate to define an active region in at least the NMOS region and the PMOS region, forming recess channel structures in the active region of the NMOS region and the PMOS region, forming a gate insulating film in the recess channel structures, forming an impurity-doped first conductive layer over the gate insulating film to fill the recess channel structure, forming an undoped amorphous silicon layer over the impurity-doped first conductive layer, forming a second conductive layer over the undoped amorphous silicon layer, and patterning the second conductive layer, the undoped amorphous silicon layer, and the impurity-doped first conductive layer to form a gate.

In one embodiment, there is provided a gate electrode for a semiconductor device comprising a lower gate electrode, an upper gate electrode over the lower gate electrode, and an undoped amorphous silicon layer between the lower gate electrode and the upper gate electrode.

### BRIEF DESCRIPTION OF THE DRAWINGS

FIG. 1 is a cross-sectional view illustrating a semiconductor device according to an embodiment consistent with the present invention; and

FIGS. 2a through 2i are cross-sectional views illustrating a method for fabricating a semiconductor device according to an embodiment consistent with the present invention.

### DETAILED DESCRIPTION

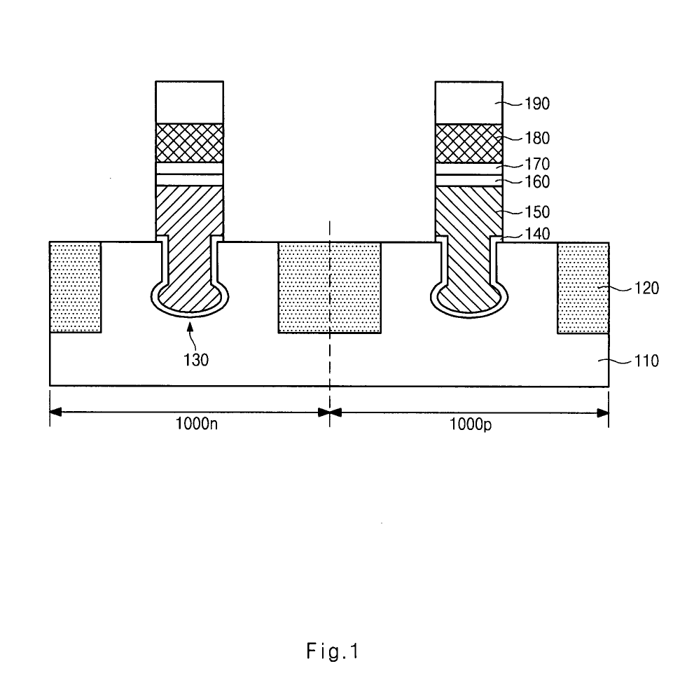

FIG. 1 is a cross-sectional view illustrating a semiconductor device according to an embodiment consistent with the present invention. The semiconductor device includes a CMOS transistor including a dual poly gate having a NMOS gate and a PMOS gate. The semiconductor device comprises a device isolation structure 120, a three-dimensional recess channel structure 130, a gate insulating film 140, a lower gate electrode 150, an undoped amorphous silicon layer 160, a barrier layer 170, and an upper gate electrode 180.

Device isolation structure 120 is disposed in a semiconductor substrate 110 including a NMOS region 1000n and a PMOS region 1000p to define an active region. Consistent with an embodiment of the present invention, three-dimensional recess channel structure 130 is formed to have a bulb-type structure. Three-dimensional recess channel structure 130 has a depth in a range of about 1,000 Å to 2,000 Å from a top surface of the active region. It is understood that recess channel structure 130 is not limited to the bulb-type structure shown in FIG. 1, but can be applied to all cell and dual poly gate structures including the three-dimensional recess channel structure.

Gate insulating film 140 is disposed over semiconductor substrate 110 in a gate region (not shown), which includes three-dimensional recess channel structure 130. Gate insulating film 140 is formed to have a thickness in a range of about 20 Å to 70 Å by a wet or dry oxidation method in a furnace at a temperature ranging from about 750° C. to 950° C. Gate insulating film 140 may be formed by a dual gate insulating film formation method in NMOS region 1000n and PMOS region 1000p. Gate insulating film 140 may also be formed by a plasma nitrified oxidation method or a radical oxidation method.

Lower gate electrode 150 is disposed over gate insulating film 140 to fill three-dimensional recess channel structure 130. Lower gate electrode 150 may be formed of a polysilicon layer doped with impurities including P. The polysilicon layer may be formed by a low pressure chemical deposition (“LPCVD”) method using a source gas including PH₃ and SiH₄ under a pressure in a range of about 5 Torr to 80 Torr and a temperature in a range of about 450° C. to 600° C. to have a thickness in a range of about 500 Å to 1,500 Å. The polysilicon layer may also be formed to have a thickness in a range of about 600 Å to 1,000 Å under a pressure in a range of about 10 Torr to 30 Torr and a temperature in a range of about 510° C. to 550° C. A dosage of PH₃ is in a range of about 1.0E20 ions/cm² to 3.0E20 ions/cm².

Undoped amorphous silicon layer 160 is disposed between upper gate electrode 180 and lower gate electrode 150. Undoped amorphous silicon layer 160 may be formed to have a thickness in a range of about 10 Å to 150 Å under a pressure in a range of about 5 Torr to 80 Torr and a temperature in a range of about 450° C. to 580° C. Undoped amorphous silicon layer 160 may also be formed to have a thickness in a range of about 30 Å to 70 Å under a pressure in a range of about 10 Torr to 20 Torr and a temperature in a range of about 450° C. to 540° C.

Barrier layer 170 is disposed between undoped amorphous silicon layer 160 and upper gate electrode 180. Barrier layer 170 may be formed of a material selected from the group consisting of a tungsten silicide (WSiₓ) layer, a titanium (Ti) layer, a titanium nitride (TiN) layer, a tungsten nitride (WN) layer, and combinations thereof. A thickness of barrier layer 170 is in a range of about 50 521 to 200 Å.

Upper gate electrode 180 is disposed over barrier layer 170. Upper gate electrode 180 may be formed of a metal layer, such as a tungsten (W) layer. A thickness of upper gate electrode 180 is in a range of about 200 Å to 600 Å.

In order to form a PMOS, lower gate electrode 150 in the PMOS region may further comprise P-type impurity ions doped by a counter doping process. The counter doping process is performed with p-type impurities including B¹¹ under a dosage in a range of about 5.0E15 ions/cm² to 5.0E17 ions/cm² and energy in a range of about 1 keV to 10 keV. The counter doping process may also be performed under a dosage in a range of about 1.0E16 ions/cm² to 9.0E16 ions/cm² and energy in a range of about 3 keV to 7 keV.

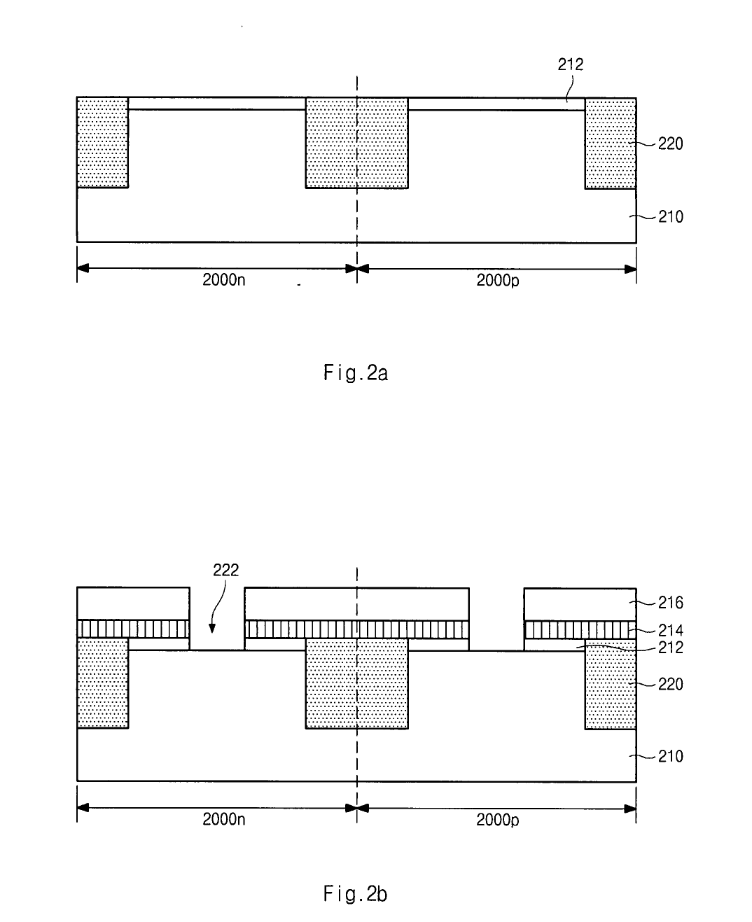

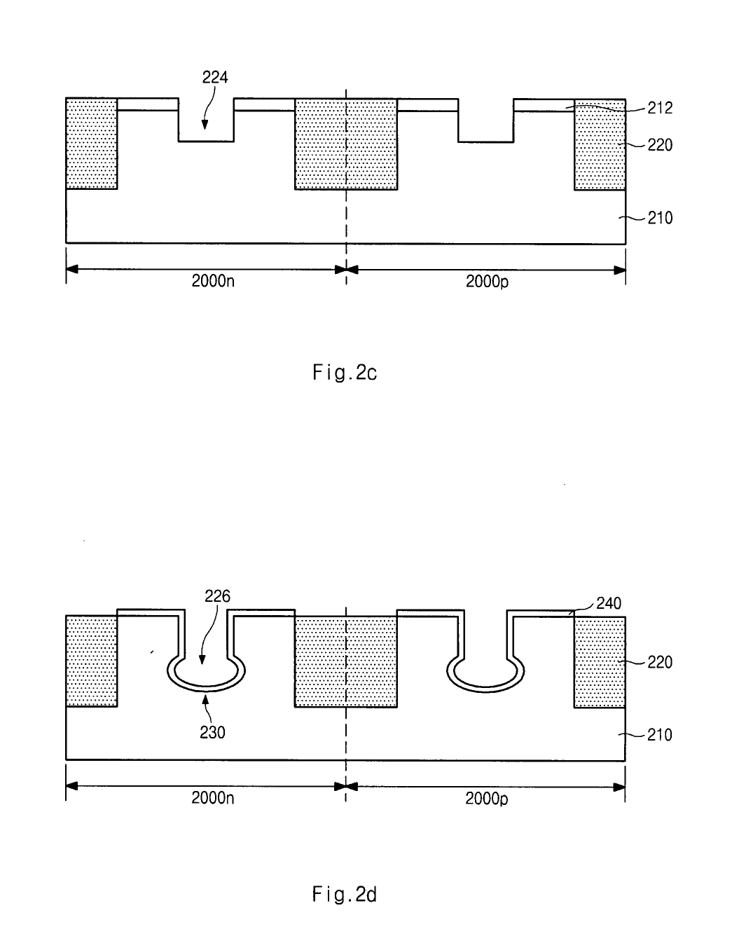

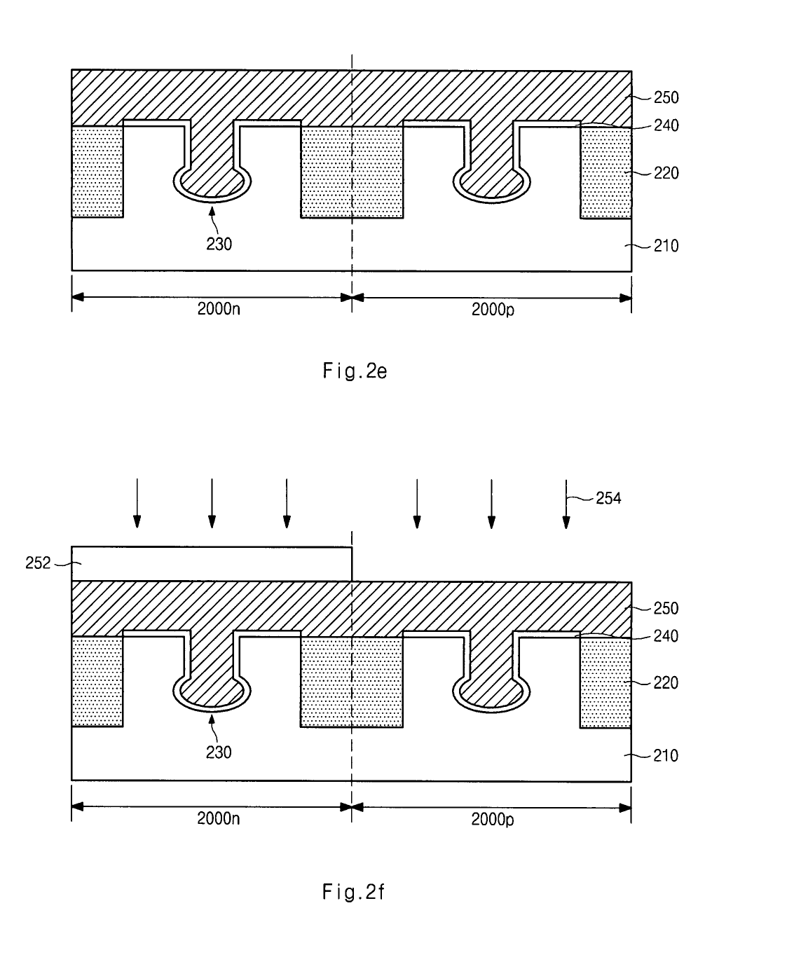

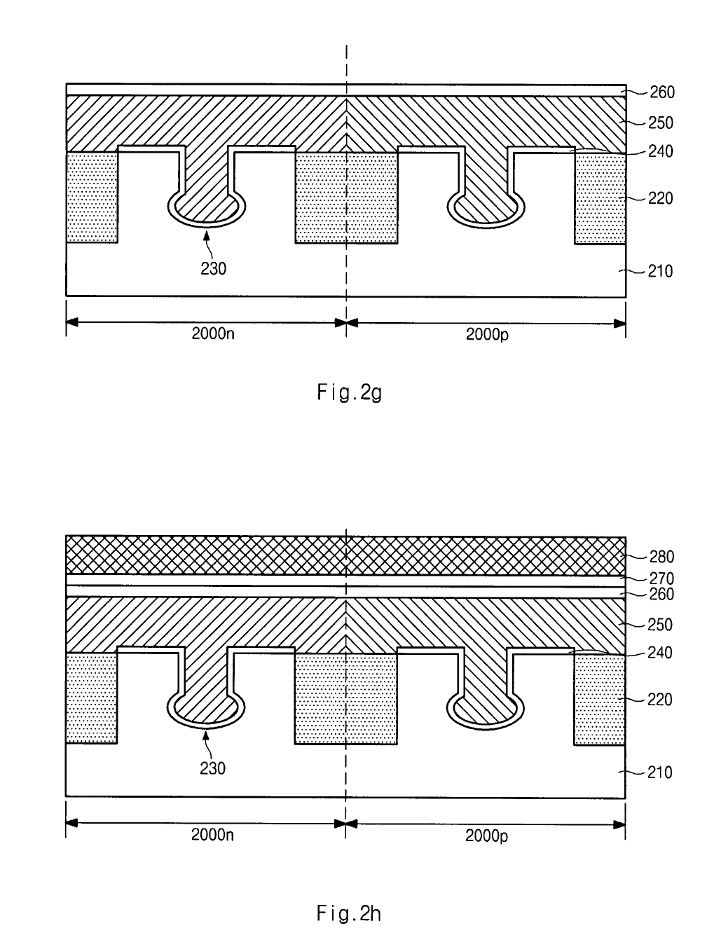

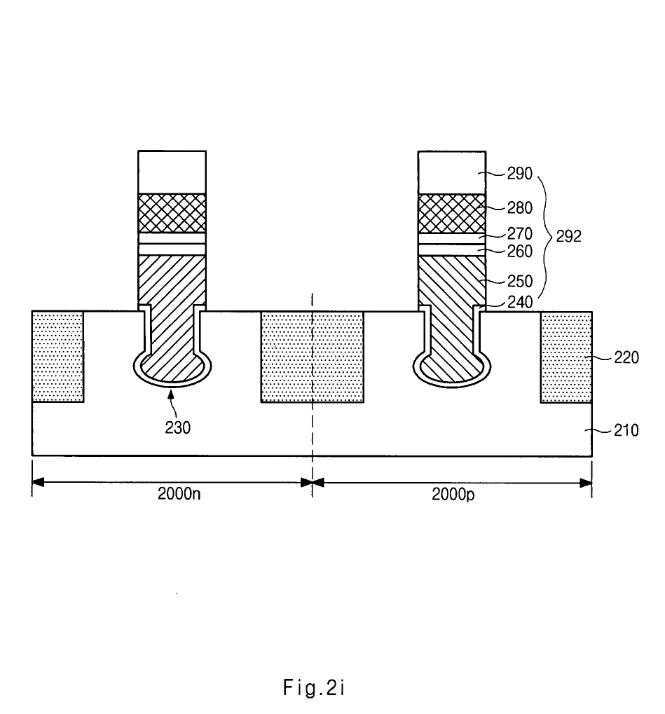

FIGS. 2a through 2i are cross-sectional views illustrating a method for fabricating a semiconductor device according to an embodiment consistent with the invention. As shown in FIG. 2a, a pad insulating film 212 is formed over a semiconductor substrate 210 including an NMOS region 2000n and a PMOS region 2000p. Pad insulating film 212 and a portion of semiconductor substrate 210 is etched using a device isolation mask to form a trench (not shown) that defines an active region. An insulating film for device isolation (not shown) is formed over semiconductor substrate 210 to fill the trench. The insulating film for device isolation is polished until pad insulating film 212 is exposed, to form a device isolation structure 220. Impurity ions are injected into semiconductor substrate 210 having device isolation structure 220 to form a well and a channel ion implantation region (not shown). In one embodiment, pad insulating film 212 may be selected from the group consisting of an oxide film, a nitride film, and a combination thereof. A thickness of pad insulating film 212 is in a range of about 50 Å to 100 Å.

Referring to FIGS. 2b and 2c, a hard mask layer 214 is formed over semiconductor substrate 210. A photoresist film (not shown) is formed over hard mask layer 214. The photoresist film is exposed and developed using a recess gate mask (not shown) to form a photoresist pattern 216 that defines a recess gate region. Hard mask layer 214 and pad insulating film 212 are etched, using photoresist pattern 216 as an etching mask, to form a recess region 222 that exposes underlying semiconductor substrate 210. Photoresist pattern 216 is then removed. A portion of exposed semiconductor substrate 210 is etched using hard mask layer 214 as an etching mask, to form a first recess 224. In one embodiment, hard mask layer 214 may include a polysilicon layer. A thickness of hard mask layer 214 is in a range of about 1,000 Å to 2,000 Å. Recess region 222 is formed in a gate region. A width of recess region 222 is smaller than the width of the gate region. In the etching process for forming first recess 224, hard mask layer 214 is simultaneously removed.

Referring to FIG. 2d, exposed semiconductor substrate 210 is further etched to form a second recess 226. First recess 224 and second recess 226 define a recess channel structure 230. A longitudinal width of second recess 226 is larger than the width of first recess 224. Pad insulating film 212 is removed to expose semiconductor substrate 210 including recess channel structure 230. A sacrificial oxide film (not shown) is formed to recover a damage generated when recess channel structure 230 is formed in semiconductor substrate 210. Impurity ions are injected into semiconductor substrate 210 in order to regulate a threshold voltage. The sacrificial oxide film is removed by a cleaning process to expose semiconductor substrate 210. A gate insulating film 240 is formed over semiconductor substrate 210 including recess channel structure 230.

In one embodiment, a vertical depth of recess channel structure 230 is in a range of about 1,000 Å to 2,000 Å. The etching process for forming second recess 226 may be performed by an isotropic etching process. The process of removing pad insulating film 212 may be performed by a wet etching process. The cleaning process for removing the sacrificial oxide film may be performed using HF. The thickness of the sacrificial oxide film may be so determined as to minimize damage in device isolation structure 220. The impurity ion-implanting process for regulating a threshold voltage may be performed using BF₂, P³¹ and As⁷⁵.

In another embodiment, gate insulating film 240 may be formed by a wet or dry oxidation method in a furnace under a temperature in a range of about 750° C. to 950° C. A thickness of gate insulating film 240 is in a range of about 20 Å to 70 Å. Gate insulating film 240 may be formed by a dual gate insulating method in NMOS region 2000n and PMOS region 2000p. Gate insulating film 240 may also be formed by a plasma nitrified oxidation method or a radical oxidation method.

Referring to FIGS. 2e and 2f, a lower gate conductive layer 250 is formed over semiconductor substrate 210 including gate insulating film 240 to fill recess channel structure 230. A photoresist film (not shown) is formed over lower gate conductive layer 250. The photoresist film is exposed and developed using a mask (not shown) for exposing the PMOS region 2000p, to form a photoresist pattern 252. An ion-implanting process 254 is performed on semiconductor substrate 210 to form a PMOS.

In one embodiment, lower gate conductive layer 250 may include a doped polysilicon layer. The polysilicon layer may be formed by a low pressure chemical deposition (“LPCVD”) method using a source gas including PH₃ and SiH₄ under a pressure in a range of about 5 Torr to 80 Torr and a temperature in a range of about 450° C. to 600° C. with a thickness in a range of about 500 Å to 1,500 Å. The polysilicon layer may also be formed to have a thickness in a range of about 600 Å to 1,000 Å under a pressure in a range of about 10 Torr to 30 Torr and a temperature in a range of about 510° C. to 550° C. A dosage of PH₃ is in a range of about 1.0E20 ions/cm² to 3.0E20 ions/cm².

In another embodiment, in order to form a PMOS, ion-implanting process 254 may be performed by a counter doping process. The counter doping process may be performed using p-type impurities including B¹¹ under a dosage in a range of about 5.0E15 ions/cm² to 5.0E17 ions/cm² and energy in a range of about 1 keV to 10 keV. The counter doping process may also be performed under a dosage in a range of about 1.0E16 ions/cm² to 9.0E16 ions/cm² and energy in a range of about 3 keV to 7 keV.

Referring to FIGS. 2g to 2i, photoresist pattern 252 is removed. An undoped amorphous silicon layer 260 for improving an interface property between a barrier layer and a metal layer is formed over semiconductor substrate 210 including NMOS region 2000n and PMOS region 2000p. A barrier layer 270 is formed over undoped amorphous silicon layer 260. An upper gate conductive layer 280 and a gate hard mask layer 290 are formed over barrier layer 270. Gate hard mask layer 290, upper gate conductive layer 280, barrier layer 270, undoped amorphous silicon layer 260, lower gate conductive layer 250, and gate insulating film 240 are patterned to form a dual poly gate 292 in NMOS region 2000n and PMOS region 2000p.

In one embodiment, undoped amorphous silicon layer 260 may be formed to have a thickness in a range of about 10 Å to 150 Å under a pressure in a range of about 5 Torr to 80 Torr and a temperature in a range of about 450° C. to 580° C. Undoped amorphous silicon layer 260 may also be formed to have a thickness in a range of about 30 Å to 70 Å under a pressure in a range of about 10 Torr to 20 Torr and a temperature in a range of about 480° C. to 540° C.

In another embodiment, barrier layer 270 may be selected from the group consisting of a tungsten silicide (WSiₓ) layer, a titanium (Ti) layer, a titanium nitride (TiN) layer, a tungsten nitride (WN) layer, and combinations thereof. A thickness of barrier layer 270 is in a range of about 50 Å to 200 Å. Upper gate conductive layer 280 may be formed of a tungsten (W) layer. A thickness of upper gate conductive layer 280 is in a range of about 200 Å to 600 Å.

The embodiments consistent with the invention are exemplified to form a dual poly gate using a bulb-type recess channel structure, but are not limited to the bulb-type recess channel structure. The embodiments consistent with the invention can be applied to form all cell and dual poly gate structures including a three-dimensional recess channel structure having a circle-type recess channel structure.

As described above, according to an embodiment consistent with the present invention, a CMOS transistor including a dual poly gate structure is formed to improve performance of the device and to enhance production yield of the device.

The above embodiments of the present invention are illustrative and not limitative. Various alternatives and equivalents are possible. The invention is not limited by the types of deposition, etching, polishing, and patterning steps described herein. Nor is the invention limited to any specific types of semiconductor device. For example, an embodiment consistent with the invention may be implemented in a dynamic random access memory (DRAM) device or a non-volatile memory device. Other additions, subtractions, or modifications are obvious in view of the present disclosure and are intended to fall within the scope of the appended claims.

What is claimed is:

1. A semiconductor device comprising:
a semiconductor substrate including an NMOS region and a PMOS region;
a device isolation structure formed on the semiconductor substrate to define an active region;
a recess channel structure formed in the active region;
a gate insulating film disposed in the recess channel structure; and
a gate including an undoped amorphous silicon layer formed over the gate insulating film, the gate filling the recess channel structure.

2. The semiconductor device of claim 1, wherein the gate is a dual poly gate comprising a stacked structure having a lower gate electrode, the undoped amorphous silicon layer, and an upper gate electrode.

3. The semiconductor device of claim 1, wherein a thickness of the undoped amorphous silicon layer is in a range of about 10 Åto 150 Å.

4. A method for fabricating a semiconductor device, the method comprising:
providing a semiconductor substrate including an NMOS region and a PMOS region;
forming a device isolation structure on the semiconductor substrate to define an active region in at least the NMOS region and the PMOS region;
forming recess channel structures in the active region of the NMOS region and the PMOS region;
forming a gate insulating film in the recess channel structures;
forming an impurity-doped first conductive layer over the gate insulating film to fill the recess channel structure;
forming an undoped amorphous silicon layer over the impurity-doped first conductive layer;
forming a second conductive layer over the undoped amorphous silicon layer; and
patterning the second conductive layer, the undoped amorphous silicon layer, and the impurity-doped first conductive layer to form a gate.

5. The method of claim 4, wherein forming the recess channel structure further comprises:
selectively etching the semiconductor substrate in the active region to form a first recess; and
etching the semiconductor substrate exposed at the bottom of the first recess to form a second recess, wherein the first recess and the second recess define the recess channel structure.

6. The method of claim 4, wherein a depth of the recess channel structure is in a range of about 1,000 Å to 2,000 Å from a top surface of the active region.

7. The method of claim 4, wherein the gate insulating film is formed to have different thicknesses in the NMOS region and the PMOS region.

8. The method of claim 4, wherein the impurity-doped first conductive layer comprises a phosphorus (P) doped polysilicon layer.

9. The method of claim 8, wherein the P doped polysilicon layer is formed by a LPCVD method using a source gas including PH₃ and SiH₄.

10. The method of claim 9, wherein a dosage of PH₃ is in a range of about 1.0E20 ions/cm² to 3.0E20 ions/cm².

11. The method of claim 4, further comprising performing a counter doping process on the conductive layer in the PMOS region.

12. The method of claim 11, wherein the counter doping process comprises doping p-type impurities including B¹¹.

13. The method of claim 4, wherein the undoped amorphous silicon layer is formed under a pressure in a range of about 5 Torr to 90 Torr and a temperature in a range of about 450° C. to 580° C. with a thickness in a range of about 10 Å to 150 Å.

14. The method of claim 4, further comprising forming a barrier layer between the undoped amorphous silicon layer and the second conductive layer.

15. The method of claim 14, wherein the barrier layer is selected from the group consisting of a tungsten silicide (WSiₓ) layer, a titanium (Ti) layer, a titanium nitride (TiN) layer, a tungsten nitride (WN) layer, and combinations thereof with a thickness in a range of about 50 Å to 200 Å.

16. The method of claim 4, wherein the second conductive layer comprises a tungsten (W) layer with a thickness in a range of about 250 Å to 600 Å.

17. The method of claim 4, wherein the gate is a dual poly gate comprising an NMOS gate structure in the NMOS region and a PMOS gate structure in the PMOS region.

18. A gate electrode for a semiconductor device, comprising:
a lower gate electrode;
an upper gate electrode over the lower gate electrode; and
an undoped amorphous silicon layer between the lower gate electrode and the upper gate electrode.

19. The gate electrode of claim 18, further comprising a barrier layer between the undoped amorphous silicon layer and the upper gate electrode.
